(19) United States
(12) Patent Application Publication
(10) Pub. No.: US 2025/0174618 A1
(43) Pub. Date: May 29, 2025

(54) DISPLAY APPARATUS AND FABRICATION METHOD OF THE SAME

(71) Applicant: Samsung Electronics Co., Ltd., Suwon-si (KR)

(72) Inventors: Suhyun Jo, Suwon-si (KR); Sammook Kang, Suwon-si (KR); Hankyu SEONG, Suwon-si (KR); Jihye YEON, Suwon-si (KR); Taesung Jang, Suwon-si (KR); Youngjo Tak, Suwon-si (KR)

(21) Appl. No.: 18/943,317

(22) Filed: Nov. 11, 2024

(30) Foreign Application Priority Data
Nov. 24, 2023 (KR) 10-2023-0165339
Apr. 9, 2024 (KR) 10-2024-0047821

(51) Int. Cl. H01L 25/18; H01L 27/12; H01L 27/15

(52) U.S. Cl. CPC H01L 25/18; H10H 29/142; H10D 86/451; H10D 86/60

(57) ABSTRACT

A display device is provided, the display device including: a support substrate occupying a first area; a driving circuit substrate occupying a second area larger than the first area and including a driving circuit; and a pixel array device occupying a third area larger than the second area, disposed on the driving circuit substrate, wherein the driving circuit substrate includes a first interconnection structure having a first bonding insulating layer and first bonding electrodes in the first bonding insulating layer, wherein the pixel array device includes a plurality of LED cells, an intermediate connection structure including an intermediate insulating layer partially covering the plurality of LED cells, and a second interconnection structure including a second bonding insulating layer bonded to the first bonding insulating layer, and second bonding electrodes in the second bonding insulating layer and respectively bonded to the first bonding electrodes.

### CROSS-REFERENCE TO RELATED APPLICATION(S)

This application claims benefit of priority to Korean Patent Application Nos. 10-2023-0165339, filed on Nov. 24, 2023 and 10-2024-0047821, filed on Apr. 9, 2024, in the Korean Intellectual Property Office, the entire contents of which are incorporated herein by reference in their entirety.

### BACKGROUND

The present inventive concept relates to a display device having LEDs and a method of manufacturing the same.

Semiconductor light-emitting diodes (LEDs) are used not only as a light source for lighting devices, but also as a light source for various electronic products. In particular, LEDs are widely used as a light source for various display devices such as TVs, mobile phones, PCs, laptop PCs, PDAs, and the like.

Existing display devices mainly comprise a display panel including a liquid crystal display (LCD) and a backlight, but recently, display devices using LEDs as pixels and not requiring a separate backlight have been developed. Such display devices can not only be miniaturized, but can also implement high-brightness display devices with superior light efficiency compared to LCDs.

### SUMMARY

An aspect of the present inventive concept is to provide a display device having excellent uniform light emission over an entire area.

According to an aspect of the present inventive concept, provided is a display device, the display device including: a support substrate occupying a first area; a driving circuit substrate occupying a second area smaller than the first area and including a driving circuit; and a pixel array device occupying a third area larger than the second area. The pixel array device is disposed on the driving circuit substrate. The driving circuit substrate includes: a semiconductor substrate having an upper surface; a plurality of transistors provided with the semiconductor substrate; a first bonding insulating layer disposed on the semiconductor substrate; and first bonding electrodes disposed in the first bonding insulating layer and electrically connected to the driving circuit. The plurality of transistors being a part of the driving circuit. The pixel array device includes: pixels each comprised of a plurality of LED cells; an intermediate insulating layer covering side surfaces and lower surfaces of the plurality of LED cells; connection electrodes disposed on the intermediate insulating layer and electrically connected to the plurality of LED cells; a second bonding insulating layer disposed on a lower surface the first bonding insulating layer; and second bonding electrodes disposed in the second bonding insulating layer and electrically connected to the connection electrodes. Each of the plurality of LED cells includes a first conductivity-type semiconductor layer, a second conductivity-type semiconductor layer, and an active layer between the first and second conductivity-type semiconductor layers. The second bonding electrodes are respectively bonded to the first bonding electrodes.

According to an aspect of the present inventive concept, provided is a display device, the display device including: a support substrate having a first region and a second region, the second region surrounding the first region; a driving circuit substrate disposed on the first region of the support substrate and including a driving circuit; a protective insulating layer disposed on the second region of the support substrate and surrounding a side surface of the driving circuit substrate; and a pixel array device disposed on the driving circuit substrate. The driving circuit substrate includes: a semiconductor substrate having an upper surface; a plurality of transistors are provided with the semiconductor substrate; a lower bonding insulating layer disposed on the semiconductor substrate; and first lower and second lower bonding electrodes disposed in the lower bonding insulating layer and electrically connected to the driving circuit. The pixel array device includes: pixels respectively comprising a plurality of LED cells, each of which including a first conductivity-type semiconductor layer; a second conductivity-type semiconductor layer; and an active layer between the first and second conductivity-type semiconductor layers. The pixel array device further includes: an intermediate insulating layer covering side surfaces and lower surfaces of the plurality of LED cells and having contact holes; a first connection electrode disposed on the intermediate insulating layer and electrically connected to the first conductivity-type semiconductor layer; second connection electrodes respectively electrically connected to the second conductivity-type semiconductor layer of the plurality of LED cells through the contact holes; an upper bonding insulating layer bonded to the lower bonding insulating layer; a first upper bonding electrode disposed in the upper bonding insulating layer and connected to the first connection electrode; and second upper bonding electrodes disposed in the upper bonding insulating layer, and respectively connected to the second connection electrodes. The first and second upper bonding electrodes are respectively bonded to the first lower and second lower bonding electrodes, respectively.

According to an aspect of the present inventive concept, provided is a method of manufacturing a display device, the method including preparing a plurality of chip-type driving circuit substrates. Each of the plurality of chip-type driving circuit substrates includes: a semiconductor substrate provided with a driving circuit; a first bonding insulating layer disposed on the semiconductor substrate; and first bonding electrodes disposed in the first bonding insulating layer and electrically connected to the driving circuit. The method further includes preparing a pixel array device including: a growth substrate; a plurality of LED cells on the growth substrate. The plurality of LED cells includes a semiconductor stack. The semiconductor stack comprises first and second conductivity-type semiconductor layers and an active layer disposed between first and second conductivity-type semiconductor layers. The pixel array device further includes an intermediate insulating layer covering the plurality of LED cells; connection electrodes disposed on the intermediate insulating layer and electrically connected to the plurality of LED cells; a second bonding insulating layer disposed on the intermediate insulating layer; and second bonding electrodes disposed in the second bonding insulating layer and electrically connected to the connection electrodes. The method further includes bonding each of the plurality of chip-type driving circuit substrates to the pixel array device thereby bonding the first and second bonding electrodes to each other; forming a protective insulating layer filling a space between the plurality of chip-type driving circuit substrates; bonding a support substrate to the plurality of chip-type driving circuit substrates; removing the growth substrate and a portion of the semiconductor stack from the pixel array device to form a plurality of undivided display devices; and dividing the plurality of undivided display devices into a plurality of display devices.

### BRIEF DESCRIPTION OF DRAWINGS

The above and other aspects, features, and advantages of the present disclosure will be more clearly understood from the following detailed description, taken in conjunction with the accompanying drawings:

FIG. 1 is a schematic perspective view of a display device according to an example embodiment of the present inventive concept;

FIG. 2 is an enlarged partial plan view of a portion A of the display device of FIG. 1;

FIG. 3 is a schematic cross-sectional view of a display device according to an example embodiment of the present inventive concept;

FIG. 4 is an enlarged partial cross-sectional view of a portion B of the display device of FIG. 3;

FIG. 5 is a partial plan view illustrating arrangement of bonding electrodes in a region of the display device of FIG. 3;

FIG. 6 is a circuit schematic of a display device according to an example embodiment of the present inventive concept;

FIG. 7 is a schematic cross-sectional view of a display device according to an example embodiment of the present inventive concept;

FIGS. 8A to 8C are cross-sectional views illustrating a method of manufacturing a chip-type driving circuit substrate according to an example embodiment of the present inventive concept;

FIGS. 9A to 9D are cross-sectional views illustrating a method of manufacturing a pixel array device according to an example embodiment of the present inventive concept;

FIGS. 10A to 10G are cross-sectional views illustrating a method of manufacturing a display device according to an example embodiment of the present inventive concept; and

FIG. 11 is a schematic diagram of an electronic device including a display device according to an example embodiment of the present inventive concept.

### DETAILED DESCRIPTION

Hereinafter, various embodiments of the present inventive concept will be described in detail with reference to the attached drawings. Unless otherwise specified, in this specification, terms such as ‘upper portion,’ ‘upper surface,’ ‘lower portion,’ ‘lower surface,’ ‘side surface,’ and the like, are based on the drawings, and may actually vary depending on the direction in which the elements are arranged.

It should be noted that items described in the singular herein, may be provided in plural, as can be seen in the various figures from the context in which they are described, and such description should be considered applicable to each of the plural, unless context indicates otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

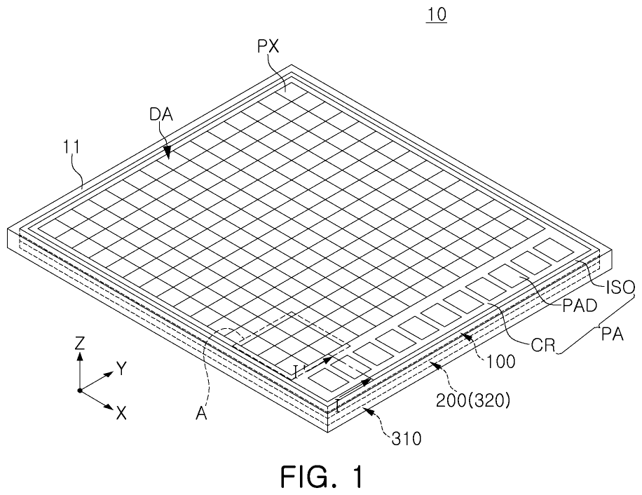

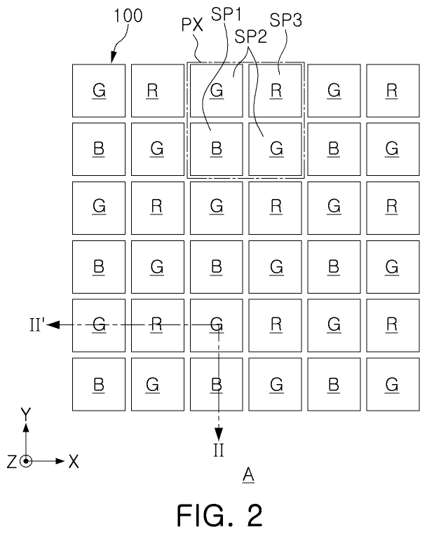

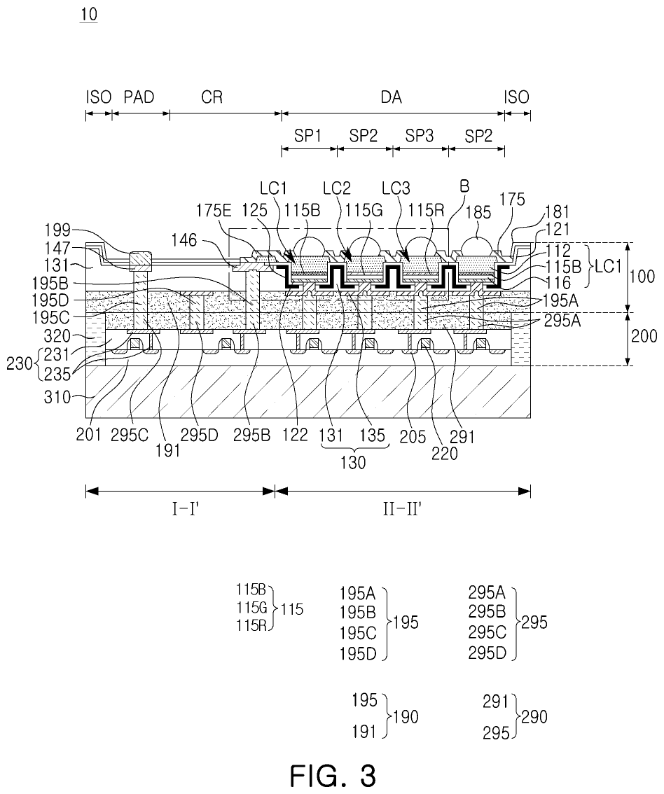

FIG. 1 is a schematic perspective view of a display device according to an example embodiment of the present inventive concept. FIG. 2 is a cross-sectional view taken along the X-Y plane of a region A of the display device of FIG. 1. FIG. 3 is a schematic cross-sectional view of a display device according to an example embodiment of the present inventive concept.

Referring to FIGS. 1 to 3, a display device 10 according to the present embodiment may include a support substrate 310, a driving circuit substrate 200 disposed on the support substrate 310 and having a driving circuit, and a pixel array device (e.g., pixel array chip) 100 disposed on the driving circuit substrate 200 and in which a plurality of pixels PX may be arranged. In the present embodiment, the driving circuit substrate 200 may be disposed between the support substrate 310 and the pixel array device 100 and may have an area smaller than those of the support substrate 310 and the pixel array device 100. The area in a horizontal plane occupied by an element may be referred to as a footprint of that element in a plan view (as viewed along the vertical direction Z). The display device 10 may include a protective insulating layer 320 surrounding a side surface of the driving circuit substrate 200 so that a space between the support substrate 310 and the pixel array device 100 may be filled. Side surfaces of the protective insulating layer 320 may be flat and coplanar with side surfaces of the support substrate 310 and the pixel array device 100, respectively. Additionally, the display device 10 may further include a frame 11 surrounding the driving circuit substrate 200 and the pixel array device 100. Terms such as “uniform,” “flat,” “same,” “equal,” “planar,” “coplanar,” “parallel,” and “perpendicular,” as used herein encompass identicality or near identicality including variations that may occur, for example, due to typical manufacturing processes. The term “substantially” may be used herein to emphasize this meaning, unless the context or other statements indicate otherwise.

The driving circuit substrate 200 may include a driving circuit including thin film transistor (TFT) cells. In some example embodiments, the driving circuit substrate 200 may further include other circuits in addition to the driving circuit for the display device. In some example embodiments, the driving circuit substrate 200 may be a flexible substrate, and the display device 10 may be implemented as a display device having a curved profile (e.g., having a curved and/or flexible display surface).

The pixel array device 100 may include a display area DA and a peripheral area PA on at least one side of the display area DA. The peripheral area PA may be disposed around the display area DA in a plan view. The display area DA may include an LED module for display. The pixel array device 100 may include a display area DA in which a plurality of pixels PX may be arranged. The peripheral area PA may include pad areas PAD, a connection region CR and an edge area ISO. The connection region CR may include wiring and/or circuits for electrically connecting the plurality of pixels PX and an external connection pad 199 the pad areas PAD

Each of the plurality of pixels PX may include first to third sub-pixels SP1, SP2, and SP3 configured to emit light of a specific wavelength, for example, a specific color, in order for the plurality of pixels to provide a color image. For example, each of the first to third sub-pixels SP1, SP2, and SP3 may comprise a corresponding one of first to third LED cells LC1 to LC3. Each of the first to third LED cells LC1 to LC3 may be configured to emit light of different colors. For example, the first to third sub-pixels SP1, SP2, and SP3 may be configured to emit blue (B) light, green (G) light, and red (R) light, respectively. In some example embodiments, in each pixel PX (also referred to as a “pixel unit”), the first to third sub-pixels SP1, SP2, and SP3 may be arranged in a Bayer pattern. The plurality of LED cells LC1 to LC3 may be arranged to be separated from each other. As shown in FIG. 2, each pixel PX may include first and third sub-pixels SP1 and SP3 (e.g., blue (B) and red (R)) arranged in a first diagonal direction and two second sub-pixels SP2 (e.g., green (G)) arranged in a second diagonal direction intersecting the first diagonal direction. In the present embodiment, it is illustrated that each pixel PX is configured so that the first to third sub-pixels SP1, SP2, and SP3 are arranged in a 2×2 Bayer pattern, but the present invention is not limited thereto, and in other example embodiments, each pixel PX may be configured in a different arrangement such as a 3×3 or 4×4 pattern. In addition, in some example embodiments, each pixel PX may include a sub-pixel configured to emit light in a color (for example, yellow light) different from the illustrated colors R, G, and B. In the pixel array device 100 of FIG. 1, it is illustrated that the plurality of pixels PX are arranged in 15×15, but the rows and columns can be any appropriate number, for example, 1,024×768. For example, depending on the desired resolution, the plurality of pixels PX may have different arrangements.

The pad areas PAD may be disposed on at least one side of the display area DA (e.g., the plurality of pixels PX) along the edge of the display device 10. The external connection pad 199 in the pad areas PAD may be electrically connected to the plurality of pixels PX and the driving circuit of the driving circuit substrate 200. The external connection pad 199 in the pad areas PAD may electrically connect the display device 10 to an external device. In some example embodiments, the number of the external connection pad 199 may vary and may be determined, for example, depending on the number of pixels PX, a driving method of the driving circuit, or the like.

The connection region CR may be an area located between the plurality of pixels PX and the pad areas PAD. Common electrode structures 146, 175, 195B, and 295B electrically connected to the plurality of pixels PX may be disposed in the connection region CR (see FIG. 3). The edge area ISO may be formed on the outer sides of the driving circuit substrate 200 and surround the driving circuit substrate 200 from a top down perspective. In the present embodiment, the edge area ISO may be an area in which the protective insulating layer 320 is located.

The frame 11 may be disposed around the pixel array device 100. The frame 11 may be provided as a guide defining a dispositional space of the display device 10. The frame 11 may include at least one of materials such as polymer, ceramic, semiconductor, or metal, for example. For example, the frame 11 may include a black matrix. However, the frame 11 is not limited to a black matrix, and may include a white matrix or a structure of another color depending on the purpose of the display device 10. For example, the white matrix may include reflective or scattering materials. In FIG. 1, the display device 10 is illustrated as having a rectangular planar structure, but may have a different shape depending on the example embodiments.

FIG. 3 is a schematic cross-sectional view of a display device according to an example embodiment of the present inventive concept, which can be understood as a combination of the cross-section along I-I′ in FIG. 1 (peripheral area PA) and the cross section along II-II′ in FIG. 2 (display area DA).

Referring to FIG. 3, as described above, the display device 10 according to the present embodiment may include a support substrate 310, a driving circuit substrate 200 on the support substrate 310, and a pixel array device 100 on the driving circuit substrate 200. The pixel array device 100 may have the same or similar area as the support substrate 310. The protective insulating layer 320 may fill a space between the support substrate 310 and the pixel array device 100 in the edge area ISO.

In some example embodiments, the protective insulating layer 320 may include silicon oxide or a silicon oxide-based insulating material or a polymer-based resin. For example, the silicon oxide-based insulating material may include TEOS (TetraEthyl Ortho Silicate), USG (Undoped Silicate Glass), PSG (PhosphoSilicate Glass), BSG (Borosilicate Glass), BPSG (BoroPhosphoSilicate Glass), FSG (Fluoride Silicate Glass), SOG (Spin On Glass), TOSZ (Tonen SilaZene), or a combination thereof. In some example embodiments, the space may remain empty without the protective insulating layer 320.

The driving circuit substrate 200 may include a semiconductor substrate 201 (e.g., including crystalline semiconductor and may be bulk Si, bulk Ge, silicon on insulator (SOI), etc.) used when manufacturing the driving circuit substrate 200. The driving circuit substrate 200 may include an interlayer connection structure 230 between the semiconductor substrate 201 and the lower interconnection structure 290. The interlayer connection structure 230 may include a wiring insulation layer 231 on the semiconductor substrate 201 and a wiring circuit (e.g., conductive patterns and conductive vias) 235 electrically connected to driving elements 220 within the wiring insulating layer 231 and/or on the semiconductor substrate 201. For example, the driving elements 220 may be disposed on an upper surface of the driving circuit substrate, and may be a plurality of transistors, which are part of the driving circuit.

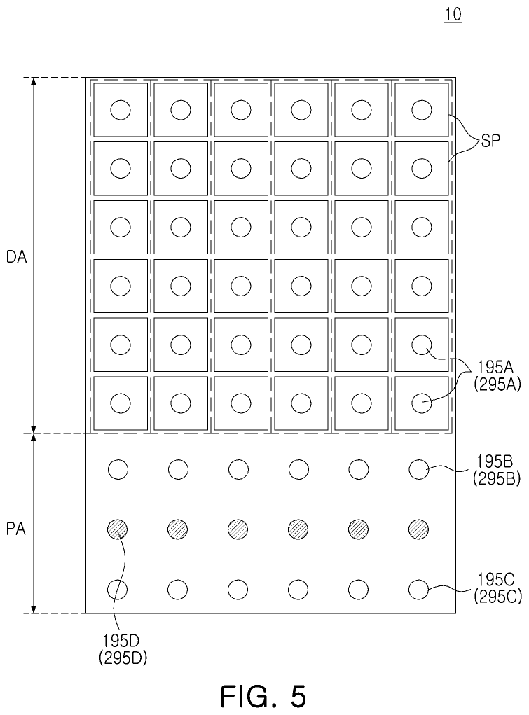

The elements 220 for the driving circuit may include thin film transistor (TFT) cells. The driving elements 220 may include source/drain regions 205. The semiconductor substrate 201 may be a semiconductor substrate, in which impurity regions including the source/drain regions 205 may be formed. The semiconductor substrate 201 may include or be, for example, a semiconductor such as silicon (Si) or germanium (Ge), or a compound semiconductor such as SiGe, SiC, GaAs, InAs, or InP. The driving circuit may include a circuit for controlling and/or driving of the pixels, particularly sub-pixels. The source region 205 of the TFT cells may be electrically connected to one electrode (e.g., 122) of LED cells LC1, LC2, and LC3 through the interlayer connection structure 230 and the lower interconnection structure 290. For example, the drain region 205 of the TFT cells may be connected to a data line through a wiring circuit 235. Gate electrodes of the TFT cells including transistors may be connected to a gate line through the wiring circuit 235. The configuration and operation of the circuit will be described in more detail with reference to FIG. 5 below.

The lower interconnection structure (also referred to as first interconnection structure) 290 may include a lower bonding insulating layer (also referred to as first bonding insulating layer) 291 and lower bonding electrodes (also referred to as first bonding electrodes) 295 disposed in the lower bonding insulating layer 291. The lower bonding electrodes 295 may be electrically connected to the driving circuit. The lower bonding electrodes 295 may be electrically connected to the wiring circuit 235. For example, the lower bonding electrodes 295 may be provided in the shape of pillars. Upper surfaces of the lower bonding electrodes 295 may have a substantially coplanar with an upper surface of the lower bonding insulating layer 291. The upper surface of the lower interconnection structure 290 (i.e., the upper surfaces of the lower bonding electrodes 295 and the lower bonding insulating layer 291) may be an upper surface of the driving circuit substrate 200 and may be provided as a bonding surface for bonding the driving circuit substrate 200 to the pixel array device 100. The lower bonding electrodes 295 may include a conductive material, for example, copper (Cu). For example, the lower bonding insulating layer 291 may include at least one of SiO, SiN, SiCN, SiOC, SiON, and SiOCN.

The pixel array device 100 employed in the present embodiment may include a plurality of LED cells LC1, LC2, and LC3 provided as light sources for a plurality of sub-pixels SP1, SP2, and SP3. The pixel array device 100 may include an intermediate connection structure 130 covering side surfaces and lower surfaces of the plurality of LED cells LC1, LC2, and LC3. The pixel array device 100 may include an upper interconnection structure 190 disposed on a lower surface of the intermediate connection structure 130.

Each of the plurality of LED cells LC1, LC2, and LC3 may include a semiconductor stack. The semiconductor stack may include a first conductivity-type semiconductor layer 112, a second conductivity-type semiconductor layer 116, and an active layer 115 between the first and second conductivity-type semiconductor layers 112 and 116. The first conductivity-type semiconductor layer 112 may include a plurality of first conductivity-type semiconductor patterns. The second conductivity-type semiconductor layer 116 may include a plurality of second conductivity-type semiconductor patterns. The active layer 115 may include a plurality of active patterns. In the present embodiment, the semiconductor stacks may have a structure separated into LED cells. For example, the first conductivity-type semiconductor layer 112 may include a plurality of first conductivity-type semiconductor patterns, the second conductivity-type semiconductor layer 116 may include a plurality of first conductivity-type semiconductor patterns. The active layer 115 may include first, second and third active patterns 115B, 115G and 115R, each of which is a single pattern (e.g., a monolithic pattern). Each of the plurality of LED cells LC1, LC2, and LC3 may include a corresponding one of the plurality of first conductivity-type semiconductor patterns and a corresponding one of the plurality of first conductivity-type semiconductor patterns. Between each pair of the first and second conductivity-type semiconductor patterns, a corresponding one of the first, second and third active patterns 115B, 115G and 115R may be interposed. For example, the active patterns 115B, 115G and 115R each may be located between a corresponding one of the first conductivity-type semiconductor patterns 112 and the second conductivity-type semiconductor patterns 116. The semiconductor stack may be epitaxial layers grown on a single growth substrate.

A first passivation layer 121 may be disposed on the lower and side surfaces of the plurality of LED cells LC1, LC2, and LC3. The first passivation layer 121 may surround the side surfaces and lower surfaces of the plurality of LED cells LC1, LC2, and LC3 within an intermediate insulating layer 131. Referring to FIG. 3, the first passivation layer 121 may extend into the peripheral area PA. A reflective metal layer (also referred to as a reflective layer) 125 may be disposed on the first passivation layer 121. The reflective metal layer 125 may include reflective metal patterns having a shape of a plurality of bells. Each of the plurality of LED cells LC1, LC2, and LC3 may include a corresponding one of the reflective metal patterns. The reflective metal layer 125 may surround each of the plurality of LED cells LC1, LC2, and LC3. For example, the reflective metal layer 125 may include at least one selected from the group consisting of Ag, Ni, Al, Rh, Ru, and combinations thereof.

The first conductivity-type semiconductor layer 112 may have protruding portions provided as light-emitting surfaces beyond an upper surface of the intermediate insulating layer 131. For example, the intermediate insulating layer 131 may have contact holes, which at least partially exposes contact electrodes 122. Connection electrodes may include a plurality of first connection electrodes 175 and a plurality of second connection electrodes 135. The second connection electrodes 135 may be disposed on the exposed portion of the contact electrodes 122. Through the contact holes, each of the second connection electrodes 135 may be electrically connected to the second conductivity-type semiconductor layer of the plurality of LED cells. In an embodiment, the contact electrodes 122 may not be provided, and the contact holes may at least partially expose the second conductivity-type semiconductor layer. The second connection electrodes 135 may contact the exposed portions of the second conductivity-type semiconductor layer. A second passivation layer 181 may be disposed on the upper surface of the intermediate insulating layer 131. The first and second passivation layers 121 and 181 may include at least one of an insulating material, for example, SiO2, SiN, SiCN, SiOC, SiON, and SiOCN.

As described above, the pixel array device 100 may include a display area DA in which a plurality of pixels PX are arranged, and each of first to third sub-pixels SP1, SP2, and SP3 in the plurality of pixels PX may be arranged according to a predetermined pattern (e.g., Bayer pattern). The plurality of LED cells LC1, LC2, and LC3 respectively have a micro LED structure, and may be formed to correspond to the first to third sub-pixels SP1, SP2, and SP3, respectively. The LED cells LC (i.e., LC1, LC2, and LC3) may be arranged in a plurality of rows and a plurality of columns in a plan view (see FIG. 2).

The plurality of LED cells LC1, LC2, and LC3 may be provided as light sources of the sub-pixels SP1, SP2, and SP3, and may include active patterns 115B, 115G, and 115R emitting light of different wavelengths. Each of the first LED cells LC1 may include a first active pattern (also referred to as a blue active pattern) 115B configured to emit blue light, for example, light with a wavelength of 430 nm to 480 nm, and may be provided as a blue sub-pixel SP1. Each of the second LED cells LC2 may include a second active pattern (also referred to as a green active pattern) 115G configured to emit green light, for example, light with a wavelength of 510 nm to 550 nm, and may be provided as a green sub-pixel SP2. Each of the third LED cells LC3 may include a third active pattern (also referred to as a red active pattern) 115R configured to emit red light, for example, light with a wavelength of 620 nm to 660 nm, and may be provided as a red sub-pixel SP3.

In the present embodiment, the semiconductor stack may include nitride epitaxial layers. The active patterns 115B, 115G, and 115R may include a quantum well layer having different indium contents from each other. In some example embodiments, the active patterns 115B, 115G, and 115R may have a multiple quantum well (MQW) structure in which quantum barrier layers and quantum well layers are alternately arranged. For example, the quantum well layer may be formed of InxGa1-xN (0<x≤1), and the quantum barrier layer may be formed of GaN or AlGaN. For example, the quantum well layer of the red active pattern 115R may have an indium content of 25 to 35%, and the quantum well layers of the green and blue active patterns 115G and 115B may have an indium content of 15 to 20% and an indium content of 10 to 15%, respectively. The active patterns 115B, 115G, and 115R may have different pairs. For example, the red active pattern 115R may have a larger number of pairs than the green and blue active patterns 115G and 115B.

The first conductivity-type semiconductor layer 112 and the second conductivity-type semiconductor layer 116 may be nitride semiconductor layers having a composition of n-type and p-type InxAlyGa1-x-yN (0≤x<1, 0≤y<1, 0≤x+y<1), respectively. For example, the first conductivity-type semiconductor layer 112 may be n-type gallium nitride (n-GaN) layers doped with silicon (Si), germanium (Ge), or carbon (C). The second conductivity-type semiconductor layer 116 may be p-type gallium nitride (p-GaN) layers doped with magnesium (Mg) or zinc (Zn). In some example embodiments, each of the first conductivity-type semiconductor layer 112 and the second conductivity-type semiconductor layer 116 may include a plurality of layers having different doping concentration and/or different composition. The first conductivity-type semiconductor layer 112 and the second conductivity-type semiconductor layer 116 may further include an aluminum indium gallium phosphide (AlInGaP) or aluminum indium gallium arsenide (AlInGaAs)-based semiconductor layer, in addition to the nitride semiconductor layers. The side surfaces of each of the LED cells LC1, LC2, and LC3 may have a right angle or an inclination angle close to a right angle with respect to the upper surface of the support substrate 310. For example, the inclination angle may range from about 85 degrees to about 95 degrees.

The intermediate connection structure 130 may include an intermediate insulating layer 131 covering side surfaces and lower surfaces of the plurality of LED cells LC1, LC2, and LC3. The intermediate connection structure 130 may include second connection electrodes 135 disposed on the intermediate insulating layer 131 and connected to drive the plurality of LED cells LC1, LC2, and LC3.

The upper interconnection structure 190 may include an upper bonding insulating layer 191 disposed on a lower surface of the intermediate connection structure 130 (e.g., the intermediate insulating layer), and upper bonding electrodes 195 electrically connected to the first connection electrodes 175 in the upper bonding insulating layer 191. In the present specification, the upper interconnection structure 190 is also referred to as “second interconnection structure.” The upper bonding electrodes 195 may be electrically connected to the connection electrodes 175 and 135. For example, each of the upper bonding electrodes 195 may have a post-like shape. The upper surfaces of the upper bonding electrodes 195 may have a substantially coplanar with the upper surface of the upper bonding insulating layer 191.

The upper surface of the upper interconnection structure 190 (i.e., the upper surfaces of the upper bonding electrodes 195 and the upper bonding insulating layer 191) may be a lower surface of the pixel array device 100 and may be provided as a bonding surface for bonding the pixel array device 100 to the driving circuit substrate 200. The upper bonding electrodes 195 may include a conductive material, for example, copper (Cu). For example, the upper bonding insulating layer 191 may include at least one of SiO, SiN, SiCN, SiOC, SiON, and SiOCN.

The lower bonding electrodes 295 of the driving circuit substrate 200 and the upper bonding electrodes 195 of the pixel array device 100 may be bonded to each other to provide an electrical connection path between the driving circuit substrate 200 and the pixel array device 100. In addition, the upper bonding insulating layer 191 of the pixel array device 100 may be bonded to the lower bonding insulating layer 291 of the driving circuit substrate 200. As described above, the driving circuit substrate 200 and the pixel array device 100 may be coupled to each other by bonding the lower bonding electrodes 295 and the upper bonding electrodes 195 and by bonding the lower bonding electrodes 295 and the upper bonding insulating layer 191. The driving circuit substrate 200 and the pixel array device 100 may be bonded by a hybrid bonding including a copper (Cu)-copper (Cu) bonding and a dielectric-dielectric bonding where the different copper elements and different dielectrics contact and merge with each other, respectively. The driving circuit substrate 200 and the pixel array device 10 and may be connected to each other via bonding and need not be connected with an adhesive layer. The bonding of the lower bonding electrodes 295 and the upper bonding electrodes 195 may be, for example, a copper (Cu)-copper (Cu) bonding. The bonding of the lower bonding insulating layer 291 and the upper bonding insulating layer 191 may be a dielectric-dielectric bonding, for example, a SiCN—SiCN bonding. The upper bonding electrodes 195 may include first upper bonding electrodes 195A, second upper bonding electrodes 195B and third upper bonding electrodes 195C. The lower bonding electrodes 295 may include first lower bonding electrodes 295A, second lower bonding electrodes 295B and third lower bonding electrodes 295C.

Landing electrodes 146, the first connection electrodes 175, second lower and second upper bonding electrodes (also referred to as first and second common bonding electrodes 295B and 195B) may be collectively referred to as common electrodes. The common electrodes may be electrically connected to the plurality of pixels PX, and may be disposed in the connection region CR (see FIG. 3). The common electrodes may be commonly connected to the first conductivity-type semiconductor layer 112 of the plurality of LED cells LC1, LC2, and LC3. In an embodiment, the include landing electrodes 146, the first connection electrodes 175, second upper and second lower bonding electrodes 195B and 295B may be respectively electrically connected to the plurality of sub-pixels in a corresponding one of the plurality of pixels PX.

In the present embodiment, the first connection electrode 175 may be electrically connected to each of the first conductivity-type semiconductor patterns of the plurality of LED cells LC1, LC2, and LC3. The plurality of second connection electrodes 135 respectively electrically connected to the second conductivity-type semiconductor patterns of the plurality of LED cells LC1, LC2, and LC3. The first connection electrode 175 may be provided as a portion of common electrodes for the plurality of LED cells LC1, LC2, and LC3, and the plurality of second connection electrodes 135 may be provided as a portion of each individual electrodes (e.g., second connection electrodes 135) to selectively drive the plurality of LED cells LC1, LC2, and LC3.

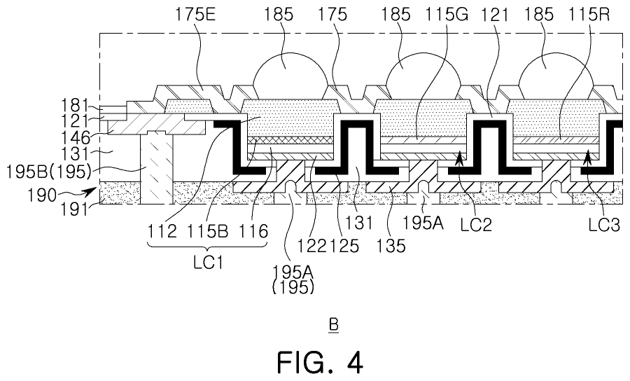

FIG. 4 is an enlarged partial cross-sectional view of a portion B of the display device of FIG. 3.

Referring to FIG. 4, the plurality of LED cells LC1, LC2, and LC3 may include contact electrodes 122 located on the second conductivity-type semiconductor layer 116. The contact electrode 122 may include or be formed of a highly reflective ohmic contact material or a transparent electrode material. The plurality of second connection electrodes 135 may be disposed on the intermediate insulating layer 131 and electrically connected to the second conductivity-type semiconductor layer 116 through the contact electrode 122.

In the present embodiment, the first connection electrode 175 may be disposed on the intermediate insulating layer 131 and may be commonly connected to each of the first conductivity-type semiconductor patterns of the plurality of LED cells LC1, LC2, and LC3. The first connection electrode 175 may be connected to the protruding portion of the first conductivity-type semiconductor layer 112. The landing electrode 146, which is a portion of common electrodes, may be disposed in the connection region CR of the intermediate insulating layer 131, and the first connection electrode 175 may have an extension portion 175E connected to the landing electrode 146. The landing electrode 146 may be buried in the intermediate insulating layer 131. At least a portion of the landing electrode 146 may be exposed on the upper surface of the intermediate insulating layer 131, and the exposed portion may contact the extension portion 175E.

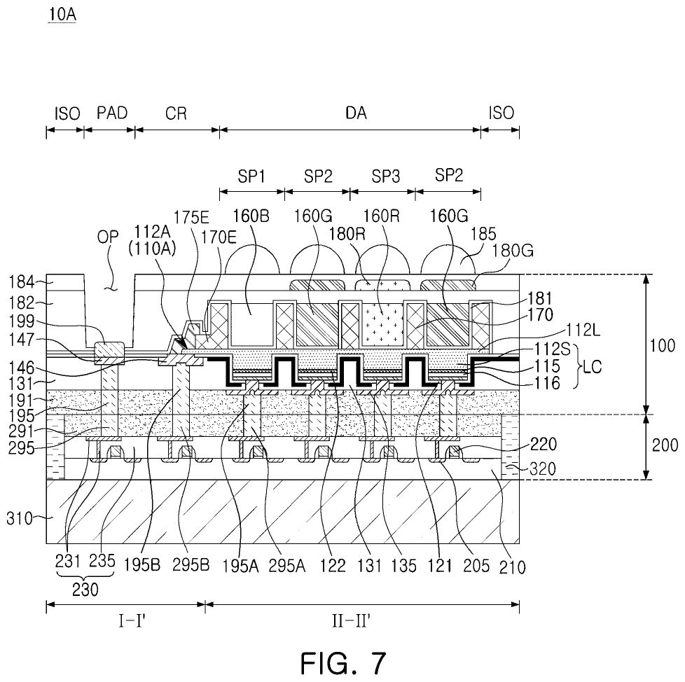

In some example embodiments, the plurality of LED cells LC1, LC2, and LC3 may be connected to each other by a connecting part 112L of the first conductivity-type semiconductor layer 112 (see FIG. 7), and the first connection electrode 175 may be disposed within the intermediate insulating layer 131 and connected to the connecting part 112L.

The second lower bonding electrodes 295B may be located in the display area DA, and respectively electrically connected to the plurality of second connection electrodes 135. The second lower bonding electrode 295B located in the peripheral circuit area and electrically connected to the first connection electrode (i.e., the extension portion 175E). The first upper bonding electrodes (also referred to as cell bonding electrodes) 195a may be located in the display area DA, and respectively electrically connected to the plurality of second connection electrodes 135. The second upper bonding electrodes (also referred to as a second upper bonding electrode) 195B located in the peripheral circuit area and electrically connected to the extension portion 175E.

The first upper bonding electrodes 195A and the first lower bonding electrodes 295A may electrically connect each of the second connection electrodes 135, which are individual electrodes, to a driving circuit. The second upper and second lower bonding electrodes 195B and 295B may electrically connect the first connection electrode 175, which is a common electrode, to the driving circuit. In the present embodiment, the second upper bonding electrode 195B may penetrate not only the upper bonding insulating layer 191 but also the intermediate insulating layer 131 to be connected to the landing electrode 146 to which the first connection electrode 175 is connected.

As described above, by bonding the first upper and first lower bonding electrodes 195A and 295A and the second upper and second lower bonding electrodes 195B and 295B, the plurality of LED cells LC1, LC2, and LC3 may be connected to a driving circuit so that the LED cells can be individually driven. The display device 10 according to the present embodiment may include a pad electrode 147 located in the pad area PAD. Similarly to the landing electrode 146, the pad electrode 147 may be buried in the intermediate insulating layer 131. At least a portion of the pad electrode 147 may be exposed on the upper surface of the intermediate insulating layer 131, and the exposed portion may contact the external connection pad 199.

The external connection pad 199 may be disposed on the pad electrode 147. The external connection pad 199 may include metal, such as gold (Au), silver (Ag), or nickel (Ni). Third upper bonding electrode (also referred to as a pad bonding electrode) 195C and third lower bonding electrode 295C may electrically connect the pad electrode 147 to the driving circuit. In the present embodiment, the third upper bonding electrode 195C, similarly to the second upper bonding electrode 195B, may penetrate not only the upper bonding insulating layer 191 but also the intermediate insulating layer 131, to be connected to the pad electrode 147.

In the present embodiment, the lower bonding electrodes 295 may include a lower dummy bonding electrode 295D which is not connected to the driving circuit (e.g., electrically isolated from the driving circuit). The upper bonding electrodes 195 may include an upper dummy bonding electrode 195D which is connected to the lower dummy bonding electrode 295D and is not connected to the plurality of LED cells LC1, LC2, and LC3. The upper and lower dummy bonding electrodes 195D and 295D may be arranged or disposed at uniform intervals from the other ones of the upper and lower bonding electrodes 195 and 295 in a plan view.

Microlenses 185 may be disposed on each of the LED cells LC1, LC2, and LC3 to focus light emitted from the LED cells LC1, LC2, and LC3. For example, the microlenses 185 may be disposed on the first conductivity-type semiconductor layer 112 of the plurality of LED cells LC1, LC2, and LC3. In the present embodiment, the microlenses 185 may be disposed in a protruding portion of the first conductivity-type semiconductor layer 112. A lens formation area of the protruding portion may be defined by the first connection electrodes 175. For example, the microlenses 185 may have a diameter larger than widths of the LED cells LC1, LC2, and LC3 in X- and Y-directions. The microlenses 185 may be formed of, for example, a transparent photoresist material or a transparent thermosetting resin film.

FIG. 5 is a partial plan view illustrating an arrangement of bonding electrodes in one region of the display device of FIG. 3.

Referring to FIG. 5, the first to third upper bonding electrodes 195A, 195B and 195C may be arranged at relatively uniform intervals in a display area DA, but in a peripheral area PA. The first to third lower bonding electrodes 295A, 295B and 295C may be arranged at relatively uniform intervals in a display area DA, but in a peripheral area PA. In detail, second upper and second lower bonding electrodes 195B and 295B and third upper and third lower bonding electrodes 195C and 295C may be arranged at different intervals from those of first upper and first lower bonding electrodes 195A and 295A. However, by utilizing the upper and lower dummy bonding electrodes 195D and 295D, the upper and lower bonding electrodes 195 and 295 as a whole may be distributed with a uniform interval or intervals close to a uniform interval over the entire area of at least portions of the display devise in a plan view. The upper and lower dummy bonding electrodes 195D and 295D may be not connected to the plurality of LED cells LC1, LC2, and LC3 (e.g., electrically isolated from the plurality of LED cells). By arranging the upper and lower bonding electrodes 195 and 295 at substantially uniform intervals over the entire area, not only a smooth planarization process when manufacturing each upper and lower interconnection structures 190 and 290, but also sufficient rigidity may be secured in subsequent bonding.

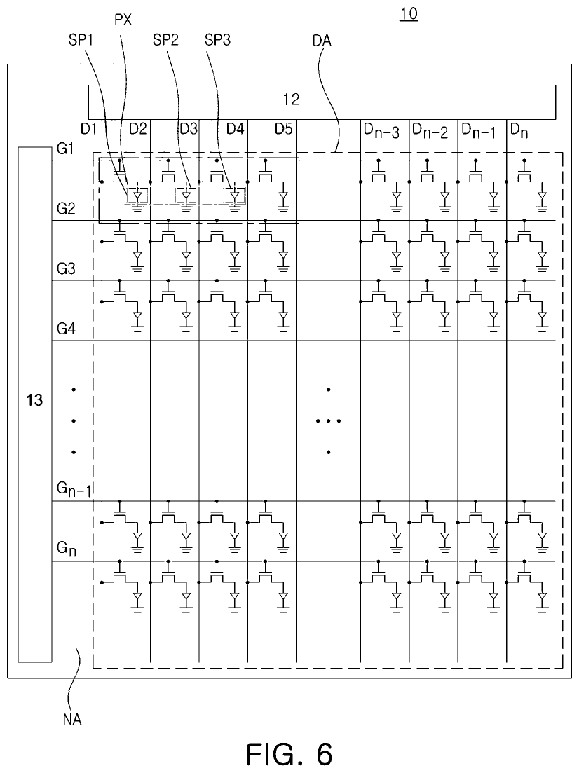

FIG. 6 is a circuit schematic of a display device 10 according to an example embodiment of the present inventive concept.

Referring to FIG. 6, a display device 10 in which n×n sub-pixels are arranged is illustrated. First to third sub-pixels SP1, SP2, and SP3 may respectively receive a data signal through data lines D1-Dn, which are columnar paths, for example, in a vertical direction. The first to third sub-pixels SP1, SP2, and SP3 may receive a control signal (e.g., a gate signal) through gate lines G1-Gn, which are row paths, for example, in a horizontal direction.

A plurality of pixels PX including the first to third sub-pixels SP1, SP2, and SP3 may be provided in a matrix in a display area DA. The display area DA may be an active area as a display area for the user. A non-active area NA (or a peripheral area PA) may be formed along one or more edges of the display area DA. The non-active area NA may extend along an outer periphery of a panel of the display device 10.

A driving circuit (e.g., a driver) may include first and second driver circuits 12 and 13, which may be employed to control the operation of the pixels PX (first to third sub-pixels SP1, SP2, and SP3). Some portion or all of the first and second driver circuits 12 and 13 may be implemented in the driving circuit substrate 200. The first and second driver circuits 12 and 13 may be in the form of semiconductor integrated circuits. For example, the driving circuit may be in the form of thin film transistor panel circuits, or other suitable circuits. At least portion of a driving circuit may be disposed in the non-active area NA. The first and second driver circuits 12 and 13 may be disposed in the non-active area NA of the display device 10. The first and second driver circuits 12 and 13 may include a microprocessor, a memory as a storage, a processing circuit, and a communication circuit.

The plurality of pixels PX are driven through the data lines D1-Dn and the gate lines G1-Gn by the first and second driver circuits 12 and 13. In an embodiment of the invention, thin film transistors are used as a part of the driving circuit. The thin film transistors may be connected to a corresponding one of the sub-pixels SP1, SP2, and SP3.

In order to display an image by the pixels PX, the first driver circuit 12 may supply image data to the data lines D1-Dn, and may provide a clock signal and other control signals to the second driver circuit (also referred to as a gate driver circuit) 13. The second driver circuit 13 may be implemented using an integrated circuit and/or a thin film transistor circuit. A gate signal for controlling the first to third sub-pixels SP1, SP2, and SP3 may be transmitted through the gate lines G1-Gn of the display device 10.

FIG. 7 is a schematic cross-sectional view of a display device according to an example embodiment of the present inventive concept.

It can be understood that a display device 10A according to the present embodiment is similar to the display device 10 illustrated in FIGS. 1 to 6. In addition, unless otherwise stated, the components of the present embodiment may be understood by referring to the description of the same or similar components of the display device 10 shown in FIGS. 1 to 6.

The display device 10A may be configured so that a plurality of LED cells LC emit light of the same wavelength (i.e., the same color). The display device 10A may have wavelength conversion patterns 160B, 160G, and 160R, and color filters 180G and 180R. A plurality of conductive partition walls (also referred to as a conductive barrier structure) 170 may be disposed between the wavelength conversion patterns 160B, 160G, and 160R. The conductive partition walls 170 may be electrically connected to each other.

Similar to the previous embodiment, the pixel array device 100 may include a plurality of LED cells LC provided as light sources for the first to third sub-pixels SP1, SP2, and SP3. Each of the LED cells LC may include an active layer 115. The active layer 115 may include active patterns configured to emit light having a wavelength of blue light. The semiconductor stack of the plurality of LED cells LC may not be completely separated. The first conductivity-type semiconductor layer of the plurality of LED cells LC is a pattern element of a patterned homogenous layer. For example, the first conductivity-type semiconductor layer 112 as a first conductivity-type semiconductor layer pattern (e.g., a monolithic pattern) may be shared by the plurality of LED cells LC, but the invention is not limited thereto. In an embodiment, the first conductivity-type semiconductor layer 112 may be a composite layer including a plurality of first conductivity-type semiconductor sub-layers. The first conductivity-type semiconductor layer 112 may include a connecting part 112L and separated parts 112S. In the present embodiment, the first conductivity-type semiconductor layer 112, the active layer 115, and the second conductivity-type semiconductor layer 116 may be separated into a plurality of LED cells LC, while the connecting part 112L is shared by the plurality of LED cells LC. The connecting part 112L may be located on the partition walls 170 and a second passivation layer 181. A portion of the connecting part 112L on the partition walls 170 may have a constant thickness. The connecting part 112L may have a thin thickness to reduce light leakage of light emitted from a sub-pixel to other sub-pixels. The thickness of connecting part 112L may be, for example, about 1 μm or less.

In the present embodiment, the conductive barrier structure 170 may be disposed to be in contact with the upper surface of the connecting part 112L. The conductive barrier structure 170 may be provided as an electrode commonly connected to the LED cells LC. The conductive barrier structure 170 may include a metal material for ohmic contact to the connecting part. The conductive barrier structure 170 may be formed of a metal material so as to be provided as a light blocking structure to prevent light interference between the sub-pixels SP1, SP2, and SP3. For example, the conductive barrier structure 170 may include or be formed of at least one selected from the group consisting of Ag, Cr, Ni, Ti, Al, Rh, Ru, and combinations thereof.

The conductive barrier structure 170 may be provided as a single-layer or multi-layer structure. For example, the conductive barrier structure 170 may have a dual-layer structure including an ohmic contact layer in contact with the connecting part 112L and a reflective electrode layer disposed on the ohmic contact layer.

The conductive barrier structure (i.e., partition walls) 170 may be configured to define sub-pixel spaces for forming the wavelength conversion patterns 160R, 160G, and 160B in a plan view. The conductive barrier structure 170 employed in the present embodiment may have a grid or mesh shape extending along the areas between the sub-pixels SP1, SP2, and SP3 on the upper surface of the connecting part 112L. The conductive barrier structure 170 may have a relatively large contact area, and can ensure uniform current flow throughout the entire display area DA.

The conductive barrier structure 170 may have an edge area 170E extending to a peripheral area PA. The edge area 170E may be a connection region CR. For example, the edge area 170E may be located on one side of the display area DA on which pixels PX are arranged. The edge area 170E of the conductive barrier structure 170 may be connected to the landing electrode 146 through an extension electrode 175E. As described above with FIGS. 3 and 4, the landing electrode 146 may be electrically connected to the driving circuit of the driving circuit substrate 200 through a second upper bonding electrode 195B and a second lower bonding electrode 295B. The extension electrode 175E and the conductive barrier structure 170 may be referred to as a first connection electrode.

In the present embodiment, the second passivation layer (also referred to as a transparent insulating film) 181 may be formed on an upper surface and side walls of the conductive barrier structure 170. The transparent insulating film 181 may be used as a refractive index matching layer to smoothly emit light from a portion of the semiconductor stack. This transparent insulating film 181 may include a low refractive index layer. For example, the transparent insulating film 181 may include at least one of SiO2 and MgF2.

Wavelength conversion patterns 160R, 160G, and 160B may be formed in the sub-pixel space defined by the conductive barrier structure 170 in which the transparent insulating film 181 is formed. The Wavelength conversion patterns may allow for the sub-pixels SP1, SP2, and SP3 to emit light of different colors. The wavelength conversion patterns 160R, 160G, and 160B may be disposed to correspond to the LED cells LC. The wavelength conversion patterns 160R, 160G, and 160B may include a wavelength conversion material converting the wavelength of light (e.g., blue light) emitted from the LED cells LC to generate final light of the desired color from each of the sub-pixels SP1, SP2, and SP3. The wavelength conversion material may include a phosphor and/or a quantum dot. Each of the wavelength conversion patterns 160R, 160G, and 160B may be obtained by filling each of the sub-pixel spaces with a liquid binder resin in which a corresponding wavelength conversion material is dispersed, and by curing the liquid binder resin.

In an embodiment, when the active layer 115 of the plurality of LED cells LC is configured to emit blue light, the first wavelength conversion pattern 160R may be configured to convert blue light into red light, and the second wavelength conversion pattern 160G may be configured to convert blue light into green light. The third wavelength conversion pattern 160B disposed in a sub-pixel space for a blue sub-pixel may include or be formed of a transparent material such as a transparent resin. In an embodiment, the third wavelength conversion pattern 160B applied to a sub-pixel space for a blue sub-pixel may be obtained by forming an intermediate wavelength conversion material and then by replacing the intermediate wavelength conversion material with a transparent material such as a transparent resin.

Though each of the LED cells LC are described as including an active layer 115 configured to emit light having a wavelength of blue light, the present inventive concept is not limited thereto. In another example embodiment, each of the active layers 115 of the plurality of LED cells LC may be configured to emit ultraviolet light. In this case, the first wavelength conversion pattern 160R may be configured to convert the ultraviolet light into red light, the second wavelength conversion pattern 160G may be configured to convert ultraviolet light into green light, and the third wavelength conversion pattern 160B may be configured to convert ultraviolet light into blue light.

The pixel array device 100 employed in the present embodiment may further include an encapsulation layer 182 and a planarization layer 184 on the wavelength conversion patterns 160R, 160G, and 160B.

The semiconductor stack, such as the connecting part 112L, may not extend to the peripheral area PA, except for a portion of the connection region CR. The encapsulation layer 182 may be disposed to cover upper surfaces of the wavelength conversion patterns 160R, 160G, and 160B. The encapsulation layer 182 may function as a protective layer to prevent deterioration of the wavelength conversion patterns 160R, 160G, and 160B. In some example embodiments, the encapsulation layer 182 may be omitted.

Color filters 180R and 180G may be disposed on the wavelength conversion patterns 160R and 160G in the second and third sub-pixels SP2 and SP3. The color filters 180R and 180G can increase a color purity of light emitted through the first wavelength conversion pattern 160R and the second wavelength conversion pattern 160G. In some example embodiments, a color filter may be further disposed on the third wavelength conversion pattern 160B.

The planarization layer 184 may be disposed to cover upper surfaces of the color filters 180R and 180G and the encapsulation layer 182. The planarization layer 184 may be a transparent layer. In addition, microlenses 185 may be disposed on the wavelength conversion patterns 160R, 160G, and 160B. The microlenses 185 may be disposed on the planarization layer 184. The microlenses 185 may focus light incident from the wavelength conversion patterns 160R, 160G, and 160B. For example, the microlenses 185 may have a diameter larger than a width of the LED cells LC in the X- and Y-directions. The microlenses 185 may be formed of, for example, a transparent photoresist material or a transparent thermosetting resin film.

An external connection pad 199 may be disposed on the pad electrode 147 in the pad areas PAD. The external connection pad 199 may be disposed to be exposed upwardly in an area in which the connecting part 112L has been removed. The external connection pad 199 may electrically connect the driving circuit of the driving circuit substrate 200 and the external device. The external connection pad 199 may include metal, such as gold (Au), silver (Ag), nickel (Ni), and the like.

As shown in FIG. 7, in a structure of the display device 10A, the pixel array device 100 may have an area smaller than that of the driving circuit substrate 200. The pixel array device 100 may have the same or similar area as the support substrate 310. The protective insulating layer 320 may fill a space between the support substrate 310 and the pixel array device 100 in the edge area ISO.

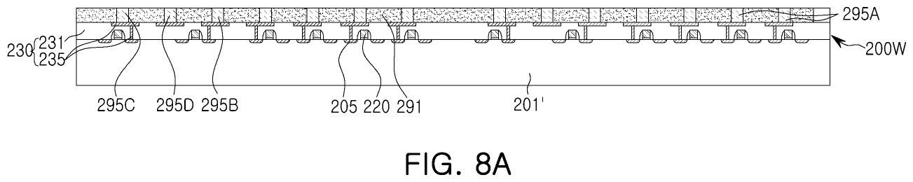

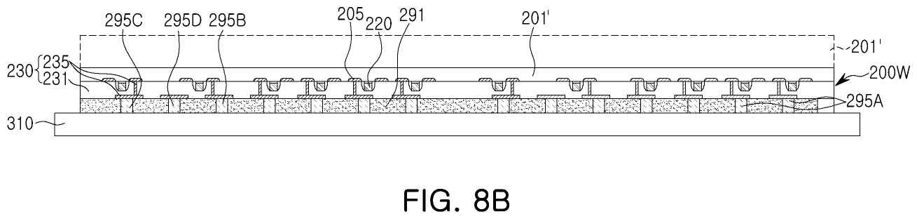

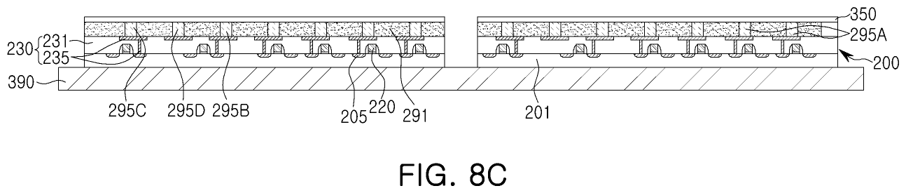

FIGS. 8A to 8C are cross-sectional views illustrating a manufacturing process of a chip-type driving circuit substrate according to an example embodiment of the present inventive concept.

Referring to FIG. 8A, a wafer-level driving circuit substrate 200W is prepared.

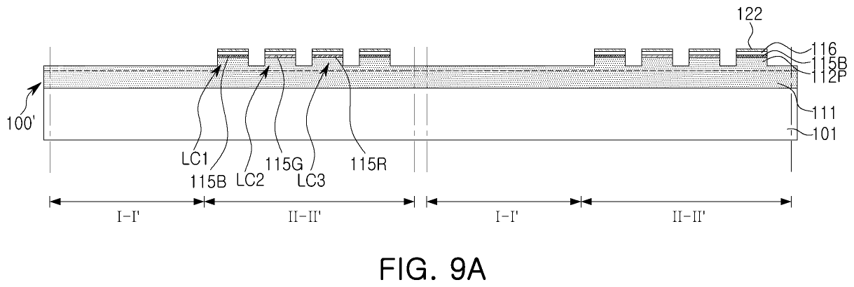

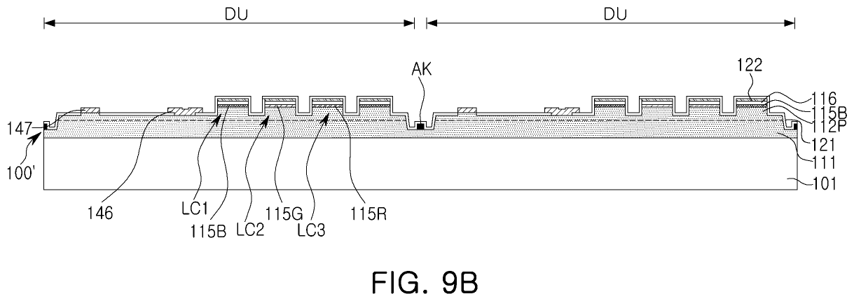

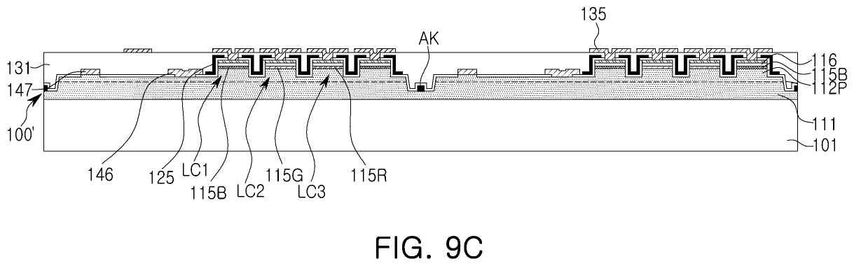

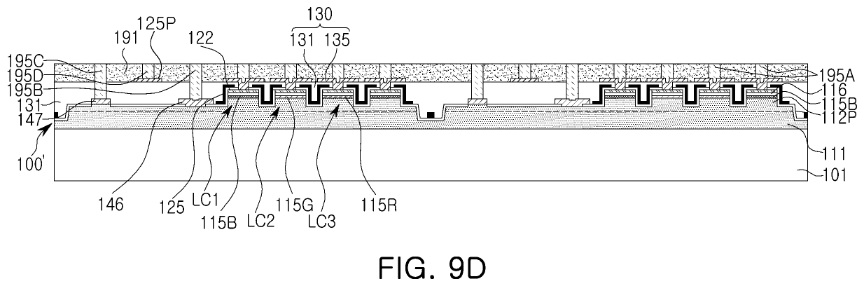

Elements for a driving circuit may be formed on an upper surface (i.e., active surface) of a wafer-level semiconductor substrate 201′ using a semiconductor manufacturing process. The driving circuit may be a TFT circuit for driving a display. Next, an interlayer connection structure 230 may be formed on the wafer-level semiconductor substrate 201′. The interlayer connection structure 230 may include a wiring insulating layer 231 and a wiring circuit 235 electrically connected to the driving elements 220 within the wiring insulating layer 231 or in the wafer-level semiconductor substrate 201′. A first interconnection structure may be formed on the interlayer connection structure 230. The first interconnection structure may include a first bonding insulating layer 291 and first bonding electrodes 295. The first bonding electrodes 295 may be disposed in the first bonding insulating layer 291 and electrically connected to the driving circuit. The wafer-level semiconductor substrate 201′ used in this process may have a size different from that of a growth substrate 101 in FIG. 9A.

Next, referring to FIG. 8B, a process of bonding the wafer-level driving circuit substrate 200W to a first adhesive member 350 (e.g., adhesive tape), and reducing a thickness of the wafer-level semiconductor substrate 201′ may be performed. In detail, the wafer-level driving circuit substrate 200W may be arranged to face the first interconnection structure to the support substrate 310 and to face a non-active surface of the wafer-level semiconductor substrate 201′ upwardly. Next, a portion of the wafer-level semiconductor substrate 201′ may be removed by applying a grinding process to obtain a desired thickness of the wafer-level semiconductor substrate 201′.

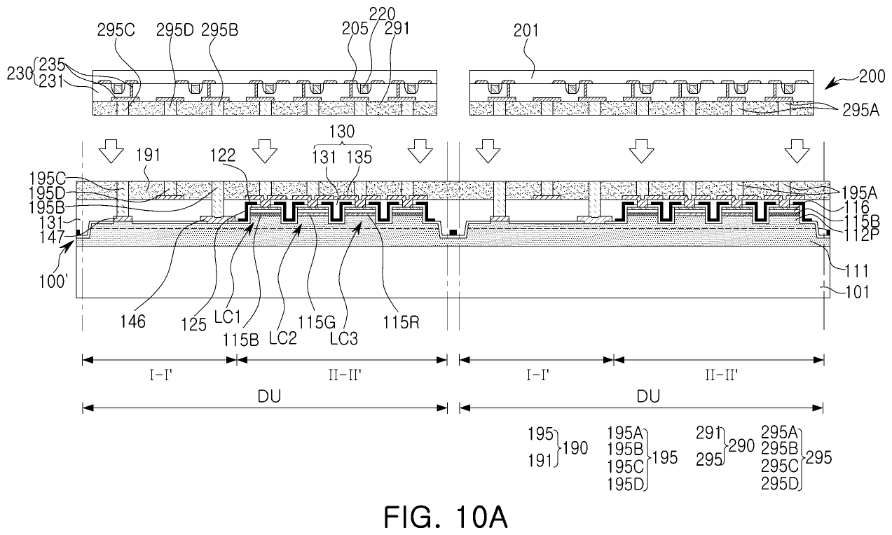

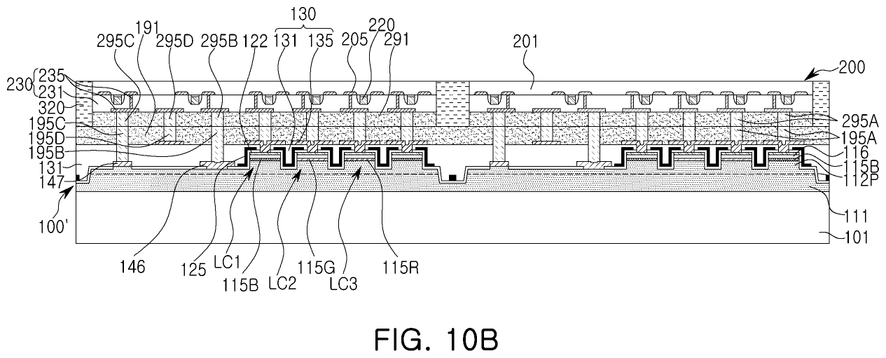

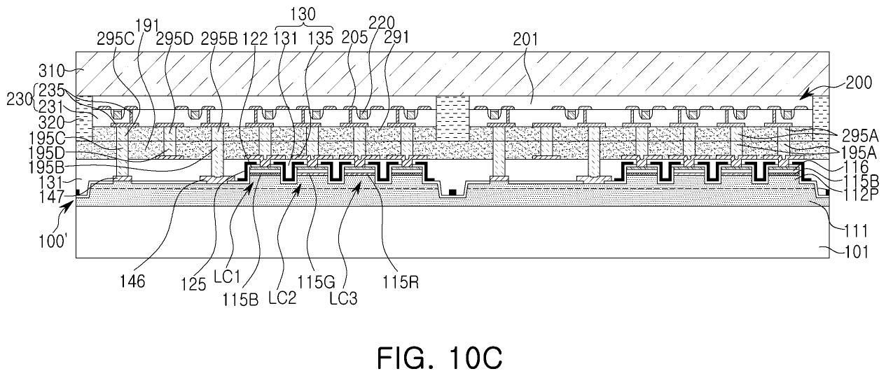

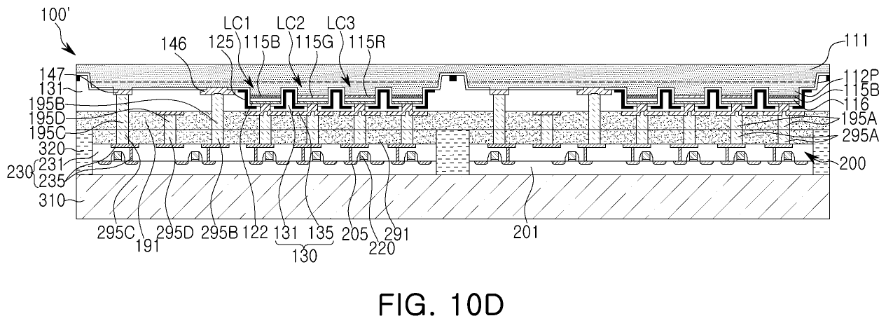

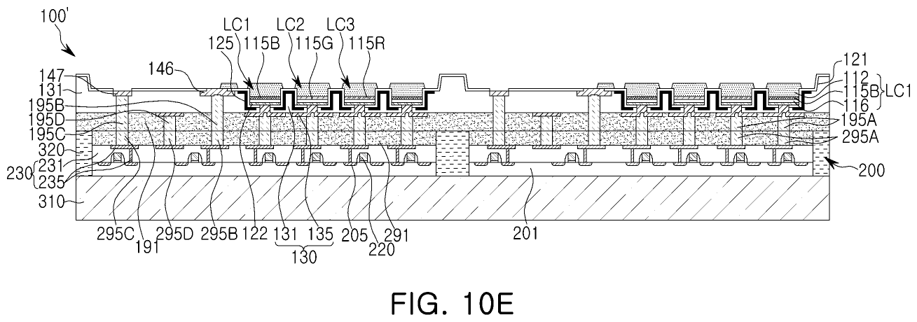

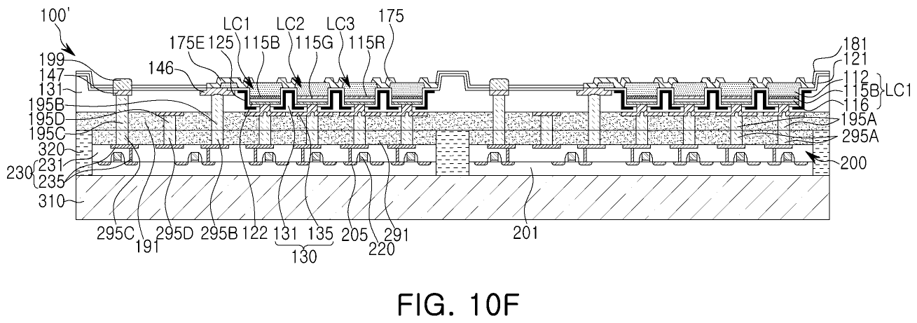

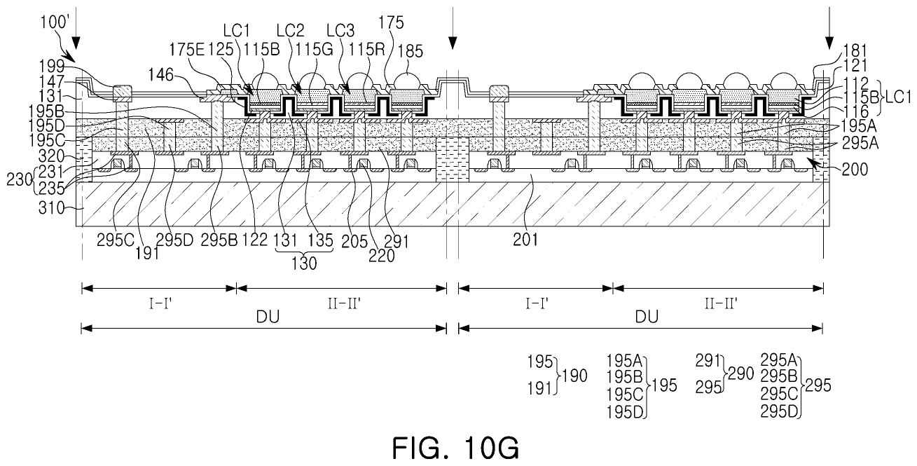

The wafer-level semiconductor substrate 201′ used in this process may have a smaller size than that of the growth substrate 101 in FIG. 9A. Therefore, bonding the wafer-level driving circuit substrate 200W to a wafer-level pixel array device 100′(shown in FIG. 10A) may be challenging. In the present invention, a plurality of chip-type driving circuit substrates 200 may be bonded to the wafer-level pixel array device 100′.

After forming the protective layer (also referred to as first adhesive member) 350 on an upper surface of the first interconnection structure 290, the wafer-level driving circuit substrate 200W may be cut into the chip-type driving circuit substrates 200. The driving circuit substrate 200 may be prepared to be smaller than the area of the final display device 10 in consideration of the transfer process.

Next, referring to FIG. 8C, after transferring the driving circuit substrate 200 may be transferred to a second adhesive member 390. The wafer-level driving circuit substrate 200W may be transferred so as to face a bottom surface of the driving circuit substrate 200 to the second adhesive member 390. Though not shown in the drawings, the first adhesive member 350 and the second adhesive member may be removed.

FIGS. 9A to 9D are cross-sectional views illustrating a manufacturing process of a wafer-level pixel array device according to an example embodiment of the present inventive concept.

Referring to FIG. 9A, a base semiconductor layer 111 may be grown on a growth substrate 101. The growth substrate 101 may be for growing a nitride single crystal, and may include, for example, at least one of sapphire, Si, SiCMgAl2O4, MgO, LiAlO2, LiGaO2, and GaN. In some example embodiments, in order to improve crystallinity and light extraction efficiency of the epitaxial layers, the growth substrate 101 may have a convex-concave structure on at least a portion of the upper surface of the growth substrate 101. For example, nano-sized, fine protrusions are formed on an upper surface of the growth substrate 101.

Epitaxial layers for a plurality of first to third LED cells LC1, LC2, and LC3 may be formed on the base semiconductor layer 111. The epitaxial layers may be or include nitride epitaxial layers for the first to third LED cells LC1, LC2, and LC3. The nitride epitaxial layers may be selectively grown in a desired area using a mask, respectively. As a result, the epitaxial layers may be formed to include a preliminary first conductivity-type semiconductor layer 112P, active patterns 115B, 115G, and 115R, and a second conductivity-type semiconductor layer 116, respectively. This nitride epitaxial layer may be formed by, for example, Metal Organic Chemical Vapor Deposition (MOCVD), Hydrogen Vapor Phase Epitaxy (HVPE), or Molecular Beam Epitaxy (MBE) processes. In some example embodiments, the base semiconductor layer 111 may include a buffer layer and an undoped nitride layer (e.g., GaN), and an upper region of the base semiconductor layer 111 may be grown and used as a preliminary first conductivity-type semiconductor layer 112P. The contact electrode 122 may be formed on an upper surface of the second conductivity-type semiconductor layer 116. For example, the contact electrode 122 may be a highly reflective ohmic contact layer or a transparent electrode layer.

In an embodiment, a contact electrode layer may be formed on the epitaxial layers, and a patterning process may be performed to obtain a plurality of second conductivity-type semiconductor patterns, a plurality of active patterns 115B, 115G, and 115R, and the contact electrode 122. In this case, the preliminary first conductivity-type semiconductor layer 112P may be partially removed so as to obtain the remaining portion of the preliminary first conductivity-type semiconductor layer 112P including a plurality of protruding portions.

Next, referring to FIG. 9B, epitaxial layers for the first to third LED cells LC1, LC2, and LC3 may be separated on the growth substrate 101 into display units DU. For example, the preliminary first conductivity-type semiconductor layer 112P may be divided into a plurality of segments on the growth substrate 101. As described above, the area of the display device may be larger than the area of the driving circuit substrate 200 for stable alignment therebetween. In addition, for the stable alignment, an align key AK may be formed in a separation area of the wafer-level pixel array device. This align key AK may be used to bond the wafer-level pixel array device 100′ and the driving circuit substrate 200.

Subsequently, a first passivation layer 121 may be formed on an upper surface of the epitaxial layers for LED cells with a uniform thickness, and then some areas thereof may be selectively removed to form openings, and a pad electrode 147 and a landing electrode 146 (see FIG. 3) connected to the preliminary first conductivity-type semiconductor layer 112P may be formed in the opening. The first passivation layer 121 may include, for example, at least one of SiO2, SiN, SiCN, SiOC, SiON, and SIOCN. The first passivation layer 121 may be formed conformally, and thus may have a substantially uniform thickness. The landing electrode 146 and the pad electrode 147 may be formed together through the same process. The landing electrode 146 and the pad electrode 147 may include a metal such as copper.

Next, referring to FIG. 9C, a reflective metal layer 125 may be formed on the first passivation layer 121, and then an intermediate connection structure including an intermediate insulating layer 131 and second connection electrodes 135 may be formed.

The reflective metal layer 125 may be formed on the first passivation layer 121 in a bell-shaped structure surrounding the plurality of LED cells LC1, LC2, and LC3. For example, the reflective metal layer 125 may include at least one selected from the group consisting of Ag, Ni, Al, Rh, Ru, and combinations thereof.

After forming the reflective metal layer 125, an intermediate insulating layer 131 may be formed to cover the plurality of LED cells LC1, LC2, and LC3. Second connection electrodes 135 penetrating the intermediate insulating layer 131 may be formed to be connected to the contact electrode 122.

In detail, a preliminary wiring insulating layer on the first passivation layer 121 to cover the plurality of LED cells LC1, LC2, and LC3, and may be formed by removing a portion of the preliminary wiring insulating layer to a desired thickness and planarizing the same. A portion of the preliminary wiring insulating layer may be removed using, for example, a planarization process such as a chemical mechanical polishing (CMP) process or an etch-back process to form an intermediate insulating layer 131 having a planar upper surface. Next, contact holes penetrating the intermediate insulating layer 131 and the first passivation layer 121 may be formed to expose the contact electrode 122. Second connection electrodes 135 may be formed by filling the contact holes with a conductive material.

Next, referring to FIG. 9D, an upper bonding insulating layer 191 may be formed on the intermediate connection structure, and upper bonding electrodes 195 may be formed.

The upper bonding insulating layer 191 may include the same or different material from the intermediate insulating layer 131. first via holes may be formed to penetrate the upper bonding insulating layer 191. First upper bonding electrodes 195A connected to the second connection electrodes 135 may be formed by filling the first via hole with a conductive material. Similarly thereto, an upper dummy bonding electrode 195D may be formed to penetrate the upper bonding insulating layer 191 and be connected to a dummy connection electrode 125P.

Second via holes may be formed to penetrate the upper bonding insulating layer 191 and the intermediate insulating layer 131. Second and third upper bonding electrodes 195B and 195C respectively connected to the landing electrode 146 and the pad electrode 147 may be formed by filling the second via holes with a conductive material. For example, the upper bonding insulating layer 191 may include at least one of SiO, SiN, SiCN, SiOC, SiON, and SiOCN. The upper bonding electrodes 195 may include a conductive material, for example, copper (Cu).

FIGS. 10A to 10G are cross-sectional views illustrating a processes for manufacturing a display device according to an example embodiment of the present inventive concept.

Referring to FIG. 10A, a plurality of chip-type driving circuit substrates 200 may be respectively bonded to a wafer-level pixel array device 100′ including LED cells LC1, LC2, and LC3.

First, the plurality of chip-type driving circuit substrates 200 may be prepared through the processes of FIGS. 8A to 8C. The plurality of chip-type driving circuit substrates 200 may be bonded on the wafer-level pixel array device 100′ in each of regions of the device units DU. The bonding may be performed by hybrid melt bonding. A lower bonding insulating layer 291 may form a dielectric-dielectric bond with an upper bonding insulating layer 191, and lower bonding electrodes 295 may be bonded to upper bonding electrode 195 by metal bonding, for example, copper (Cu)-copper (Cu) bonding. As described above, each of the chip-type driving circuit substrates 200 may be electrically/mechanically connected to the wafer-level pixel array device 100′.

Next, referring to FIG. 10B, a protective insulating layer 320 filling a space between the plurality of chip-type driving circuit substrates 200 may be formed.

Referring to FIG. 10C, a support substrate 310 may be bonded to the plurality of chip-type driving circuit substrates 200. The protective insulating layer 320 may include silicon oxide or a silicon oxide-based insulating material or a polymer-based resin. The support substrate 310 may be provided to cover the protective insulating layer 320. The support substrate 310 may be bonded to the semiconductor substrate 201 and the protective insulating layer 320.

Next, referring to FIG. 10D, a growth substrate 101 may be removed from the wafer-level pixel array device 100′.

Referring to FIG. 10E, the base semiconductor layer 111 is removed, and the preliminary first conductivity-type semiconductor layer 112P may be separated into a plurality of first conductivity-type semiconductor layer 112.

The growth substrate 101 may be removed by various processes such as laser lift-off, mechanical polishing or mechanical chemical polishing, and etching processes. In addition, removal of the base semiconductor layer 111 may be performed by a primary etching process. When the preliminary first conductivity-type semiconductor layer 112P is exposed, the removal process of growth substrate 101 may be stopped. A secondary etching process may be performed to separate the preliminary first conductivity-type semiconductor layer 112P into the first conductivity-type semiconductor layer 112. A portion of the second conductivity-type semiconductor layer 116 may be also removed from the wafer-level pixel array device 100′.

Next, referring to FIG. 10F, a first connection electrode 175 may be formed to be respectively connected to the first conductivity-type semiconductor layer 112, and an external connection pad 199 may be formed on the pad electrode 147.

In the present embodiment, the first connection electrode 175 may be formed to have an extension portion (also referred to as an extension electrode) 175E that extends to the landing electrode 146. In addition, a second passivation layer 181 may be additionally formed on the first passivation layer 121.

Next, referring to FIG. 10G, microlenses 185 may be formed on the first conductivity-type semiconductor layer 112 of the plurality of LED cells LC1, LC2, and LC3, thereby forming a plurality of undivided display devices. Final display devices 10 (in FIG. 3) may be manufactured by cutting the undivided display devices. For example, the support substrate 310 may be divided (e.g., cut) in the display units DU as indicated by vertical arrows.

In the present embodiment, the microlenses 185 may be disposed on a protruding portion of the first conductivity-type semiconductor layer 112. A lens formation area of the protruding portion may be defined by the first connection electrodes 175. The microlenses 185 may be formed of, for example, a transparent photoresist material or a transparent thermosetting resin film.

In the final structure, the pixel array device 100 may have an area smaller than that of the driving circuit substrate 200. The pixel array device 100 may have the same or similar area as the support substrate 310. The protective insulating layer 320 may fill a space of an edge area ISO between the support substrate 310 and the pixel array device 100.

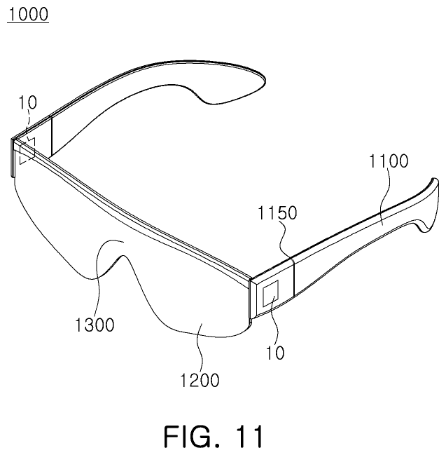

FIG. 11 is a schematic diagram of an electronic device including a display device according to an example embodiment of the present inventive concept.

Referring to FIG. 11, an electronic device 1000 according to the present embodiment may be a glasses-type display, which is a wearable device. The electronic device 1000 may include a pair of temples 1100, a pair of optical coupling lenses 1200, and a bridge 1300. The electronic device 1000 may further include a display device 10 including an image generator.

The electronic device 1000 may be a head-mounted, glass-type, or goggle-type virtual reality (VR) device that can provide virtual reality or provide both virtual images and actual external scenery, an augmented reality (AR) device, or a mixed reality (MR) device.

Temples 1100 may extend in one direction. The temples 1100 may be spaced apart from each other and extend in parallel. The temples 1100 may be folded toward a bridge 1300 using a hinge connector 1150. The bridge 1300 may be provided between optical coupling lenses 1200, to connect the optical coupling lenses 1200 to each other. The optical coupling lenses 1200 may include a light guide plate. The display device 10 may be disposed on a portion of the temples 1100 adjacent to the optical coupling lenses 1200 and may generate an image on the optical coupling lenses 1200. In some example embodiments, the display device 10 may be disposed in some areas of the optical coupling lenses 1200.

As set forth above, yield of a display device may be improved by bonding a driving circuit substrate diced in display units onto a wafer-level pixel array device. In a final display structure, the driving circuit substrate may have an area smaller than an area of a support substrate and the pixel array device, between the support substrate and the pixel array device, and an empty space therebetween may be filled with a protective insulating layer.

The various and advantageous advantages and effects of the present inventive concept are not limited to the above description, and may be more easily understood in the course of describing the specific embodiments of the present inventive concept.

While example embodiments have been shown and described above, it will be apparent to those skilled in the art that modifications and variations could be made without departing from the scope of the present inventive concept as defined by the appended claims.

1. A display device, comprising:
a support substrate occupying a first area;
a driving circuit substrate occupying a second area smaller than the first area, and including a driving circuit; and
a pixel array device occupying a third area larger than the second area, the pixel array device disposed on the driving circuit substrate,
wherein the driving circuit substrate includes:
a semiconductor substrate having an upper surface;
a plurality of transistors provided with the semiconductor substrate, the plurality of transistors being a part of the driving circuit;
a first bonding insulating layer disposed on the semiconductor substrate; and
first bonding electrodes disposed in the first bonding insulating layer and electrically connected to the driving circuit,
wherein the pixel array device includes:
pixels each comprised of a plurality of LED cells;
an intermediate insulating layer covering side surfaces and lower surfaces of the plurality of LED cells;
connection electrodes disposed on the intermediate insulating layer and electrically connected to the plurality of LED cells;
a second bonding insulating layer disposed on a lower surface the first bonding insulating layer; and
second bonding electrodes disposed in the second bonding insulating layer, and electrically connected to the connection electrodes,
wherein each of the plurality of LED cells includes a first conductivity-type semiconductor layer, a second conductivity-type semiconductor layer, and an active layer between the first and second conductivity-type semiconductor layers, and
wherein the second bonding electrodes are respectively bonded to the first bonding electrodes.

2. The display device of claim 1, further comprising:
a protective insulating layer disposed between the support substrate and the pixel array device, and surrounding a side surface of the driving circuit substrate.

3. The display device of claim 2, wherein side surfaces of the protective insulating layer are coplanar with side surfaces of the support substrate and the pixel array device, respectively.

4. The display device of claim 1, wherein the plurality of LED cells comprise first to third LED cells, and the first to third LED cells has active patterns configured to emit light of different colors.

5. The display device of claim 1, wherein the plurality of LED cells are arranged to be separated from each other, and
the first conductivity-type semiconductor layer of the plurality of LED cells has portions protruding beyond an upper surface of the intermediate insulating layer.

6. The display device of claim 5, further comprising:
a plurality of lenses respectively disposed on the first conductivity-type semiconductor layer of the plurality of LED cells.

7. The display device of claim 1, wherein the connection electrode comprises
a first connection electrode commonly electrically connected to the first conductivity-type semiconductor layer of the plurality of LED cells, and
a plurality of second connection electrodes respectively electrically connected to the second conductivity-type semiconductor layer of the plurality of LED cells.

8. The display device of claim 7, wherein:
in a plan view, the display device has a display area in which the pixels are arranged and a peripheral circuit area disposed around the display area,
the second bonding electrodes include a plurality of cell bonding electrodes located in the display area, and respectively connected to the plurality of second connection electrodes, and
the second bonding electrodes further include a common bonding electrode located in the peripheral circuit area and connected to the first connection electrode.

9. The display device of claim 8, further comprising:
an external connection pad disposed in the peripheral circuit area,
wherein the second bonding electrodes further include a pad bonding electrode connected to the external connection pad.

10. The display device of claim 8, wherein the first bonding electrodes comprise a first dummy bonding electrode disposed at uniform intervals, and the first dummy bonding electrode is electrically isolated from the driving circuit,
the second bonding electrodes comprise a second dummy bonding electrode connected to the first dummy bonding electrode and electrically isolated from the plurality of LED cells,
the first bonding electrodes are disposed at uniform intervals, and
the second bonding electrodes are disposed at uniform intervals.

11. The display device of claim 1, further comprising:
a reflective layer surrounding the side surfaces and lower surfaces of the plurality of LED cells within the intermediate insulating layer; and
a reflective layer disposed on the passivation layer.

12. The display device of claim 1, further comprising wavelength conversion patterns disposed on the first conductivity-type semiconductor layer,
wherein the connection electrodes include partition walls defining sub-pixel spaces, and the wavelength conversion patterns are respectively disposed on the sub-pixel spaces.

13. The display device of claim 12, wherein the plurality of LED cells have active patterns configured to emit light of the same color.

14. The display device of claim 12, wherein the first conductivity-type semiconductor layer of the plurality of LED cells is a pattern element of a patterned homogenous layer.

15. A display device, comprising:
a support substrate having a first region and a second region, the second region surrounding the first region;
a driving circuit substrate disposed on the first region of the support substrate and including a driving circuit;
a protective insulating layer disposed on the second region of the support substrate, and surrounding a side surface of the driving circuit substrate; and
a pixel array device disposed on the driving circuit substrate,
wherein the driving circuit substrate includes:
a semiconductor substrate having an upper surface;
a plurality of transistors provided with the semiconductor substrate;
a lower bonding insulating layer disposed on the semiconductor substrate; and
first lower and second lower bonding electrodes disposed in the lower bonding insulating layer and electrically connected to the driving circuit,
wherein the pixel array device includes:
pixels respectively comprising a plurality of LED cells, each of which including a first conductivity-type semiconductor layer, a second conductivity-type semiconductor layer, and an active layer between the first and second conductivity-type semiconductor layers;
an intermediate insulating layer covering side surfaces and lower surfaces of the plurality of LED cells, and having contact holes;
a first connection electrode disposed on the intermediate insulating layer and electrically connected to the first conductivity-type semiconductor layer;
second connection electrodes respectively electrically connected to the second conductivity-type semiconductor layer of the plurality of LED cells through the contact holes;
an upper bonding insulating layer bonded to the lower bonding insulating layer;
a first upper bonding electrode disposed in the upper bonding insulating layer and connected to the first connection electrode; and
second upper bonding electrodes disposed in the upper bonding insulating layer, and respectively connected to the second connection electrodes, and
wherein the first and second upper bonding electrodes are respectively bonded to the first lower and second lower bonding electrodes, respectively.

16. The display device of claim 15, wherein the plurality of LED cells comprise first to third LED cells, and the first to third LED cells respectively comprise active patterns configured to emit light of different colors.

17. The display device of claim 15, wherein side surfaces of the protective insulating layer are flat and coplanar with side surfaces of the support substrate and the pixel array device, respectively.

18. The display device of claim 15, further comprising:
a passivation layer disposed on the lower surfaces and the side surfaces of the plurality of LED cells, and
a reflective layer disposed on the passivation layer, and surrounding each of the plurality of LED cells.

19-20. (canceled)
